(19) United States
(12) Patent Application Publication
(10) Pub. No.: US 2015/0014752 A1
(43) Pub. Date: Jan. 15, 2015

(54) THIN BODY FET NANOPORE SENSOR FOR SENSING AND SCREENING BIOMOLECULES

(71) Applicant: International Business Machines Corporation, Armonk, NY (US)

(72) Inventors: CHRISTOPHER P. D'EMIC, Yorktown Heights, NY (US); RAMACHANDRAN MURALIDHAR, Yorktown Heights, NY (US); PHILIP J. OLDIGES, Hopewell Junction, NY (US); SUFI ZAFAR, Yorktown Heights, NY (US)

(21) Appl. No.: 13/941,124

(22) Filed: Jul. 12, 2013

(51) Int. Cl. G01N 27/414; H01L 29/66

(52) U.S. Cl. CPC G01N 27/4145; H01L 29/66477; G01N 27/4146
USPC 257/253; 438/49

(57) ABSTRACT

A thin body field effect transistor (FET) nanopore sensor includes a silicon on insulator (SOI) structure having an annular shape and comprising a source, a drain and a thin body channel interposed therebetween. A nanopore is formed in a central opening of the SOI structure. A gate dielectric is disposed on the SOI structure insulating the SOI structure from a liquid gate within the nanopore. A back gate is formed around the SOI structure. A shallow trench isolation (STI) layer is formed between the SOI structure and the back gate.

### TECHNICAL FIELD

The present disclosure relates to field effect transistor (FET) sensors and, more specifically, to thin body FET nanopore sensor for sensing and screening biomolecules.

### DISCUSSION OF THE RELATED ART

Biomolecules are molecules produced by and/or utilized by living organisms. Proper analysis of biomolecules may be highly useful in clinical and research environments. For example, analysis of biomolecules may be used to determine the presence of various proteins within a blood sample or to sequence deoxyribonucleic acid (DNA). Conventional approaches to biomolecule testing may involve the use of highly specific tests that are customized for detecting a particular biomolecule. For example, surface functionalization may be used to create a biomolecule-specific test. In such an approach, a sensing surface of the sensor may be covered with a biological coating that specifically binds the biomolecules being tested to the sensor. Biomolecules for which no such binding coating may be readily available might not even be testable using this conventional approach.

Because conventional approaches to biomolecule testing are so specialized, manufacturing of sensors may be complex and expensive as the biological coatings are applied. Moreover, such sensors may only be capable of detecting a particular type of biomolecule thereby requiring that multiple different tests be used to test a single sample for multiple biomolecules.

### BRIEF SUMMARY

A thin body field effect transistor (FET) nanopore sensor includes a silicon on insulator (SOI) structure having an annular shape and comprising a source, a drain and a thin body channel interposed therebetween. A nanopore is formed in a central opening of the SOI structure. A gate dielectric is disposed on the SOI structure insulating the SOI structure from a liquid gate within the nanopore. A back gate is formed around the SOI structure. A shallow trench isolation (STI) layer is formed between the SOI structure and the back gate.

A cavity may be formed below the liquid gate for receiving biomolecules that pass through the micropore and the liquid gate.

The cavity may include an oxide layer of the SOI structure formed below the gate and STI layer. A semiconductor layer of the SOI structure may be formed below the oxide layer. A nitride layer may be formed below the SOI structure. The oxide layer, the semiconductor layer, and the nitride layer may each have an annular shape with a relatively large central opening and the openings of the oxide layer, the semiconductor layer, and the nitride layer may together form the cavity.

The oxide layer may includes silicon dioxide. The semiconductor layer may include silicon. The nitride layer may include silicon nitride.

The thin body channel may have a thickness of between approximately 15 nm to approximately 100 nm from the source to the drain.

The thin body channel may have a thickness of approximately 25 nm from the source to the drain.

The gate dielectric may have a thickness of between approximately 1 nm to approximately 3 nm.

The nanopore may have a diameter of between approximately 3 nm to approximately 50 nm.

The nanopore may have a diameter sufficient to allow only a single biomolecule to pass therethrough at a time.

The FET nanopore sensor may be part of a sensing device including an array of similar FET nanopore sensor. The similar FET nanopore sensors may have a set of different nanopore diameters for sensing various different biomolecules.

In an NFET implementation, the source and drain regions may be formed by doping corresponding regions of the SOI structure with an n-type dopant. The source and drain regions may be doped to a concentration of approximately 1-10×10¹⁹ parts per cubic cm.

The channel region may be formed by doping corresponding regions of the SOI structure with a p-type dopant to a concentration of no more than approximately 1 to 3×10¹⁸ parts per cubic cm.

The back gate may include a conductor or a semiconductor. The back gate may include doped silicon or a metal.

The STI may include silicon dioxide.

The FET nanopore sensor may additionally include a top layer including silicon nitride formed over the STI layer and SOI structure and formed under the gate dielectric.

The gate dielectric may include hafnium(IV) oxide.

The STI may have an annular thickness of between approximately 10 nm and 100 nm, as measured between the SOI structure and the back gate.

A method for fabricating a thin body field effect transistor (FET) nanopore sensor includes providing a bulk silicon wafer including with an oxide insulator thereon, and a silicon layer over the oxide insulator, the combination of the bulk silicon wafer, the oxide insulator and the silicon layer over the oxide insulator being referred to as a silicon on insulator (SOI) structure. The silicon layer over the oxide insulator is doped to form a source, drain and a thin body channel region therebetween. One way to accomplish this is to have a pre-doped n-type layer on the oxide insulator and subsequently epitaxially growing the channel region with in situ p-type doping and then epitaxially growing the top region with in situ n-type doping. An oxide film is deposited over the SOI structure and a nitride film is deposited over the oxide film. A shallow trench isolation (STI) region is patterned and etched within the silicon layer over the oxide insulator. An oxide is deposited within the etched STI region. The oxide within the etched STI region is planarized down to the nitride film. The oxide and nitride films are removed and the oxide within the STI regions is planarized down to the silicon layer over the oxide insulator. A top nitride layer is formed over the SOI and STI regions. A bottom nitride layer is formed under the bulk silicon wafer. A window is opened within the bottom nitride layer. The bulk silicon wafer is etched through the opening of the bottom nitride layer to foil an opening in the bulk silicon wafer. The oxide insulator of the SOI wafer is etched through the opening in the bulk silicon wafer. A nanopore is formed through the top nitride layer and the SOL Walls of the nanopore and the top nitride layer are coated with a gate dielectric.

A method for detecting a biomolecule using a thin body field effect transistor (FET) nanopore sensor includes measuring a drain current without a biomolecule in a nanopore of the thin body FET nanopore sensor. A biomolecule suspended in a solution is passed through the nanopore. The drain current of the thin body FET nanopore sensor is measured as the biololecule passes from a source electrode of the sensor, past a thin body channel region of the sensor, to a drain region of the sensor. The biomolecule is identified based on a change in drain current between when the drain current was measured without the biomolecule passing through the nanopore and when the drain current was measured with the biomolecule passing through the nanopore. A sensitivity of the sensor is increased by making the annular semi-conductor region encompassing the source, channel and drain thin.

The sensitivity of the sensor may be further increased by an annular back gate surrounding the annular STI region that can be reverse biased.

### BRIEF DESCRIPTION OF THE SEVERAL VIEWS OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional schematic diagram illustrating a thin body FET nanopore sensor in accordance with exemplary embodiments of the present invention;

FIG. 2 is a diagram illustrating a cross-sectional structure of a thin body FET nanopore sensor in accordance with exemplary embodiments of the present invention;

FIG. 3 is a flow chart illustrating a method for fabricating a thin body FET nanopore sensor in accordance with exemplary embodiments of the present invention;

FIG. 4 is a flow chart illustrating an approach for sensing biomolecules within a fluid sample in accordance with exemplary embodiments of the present invention;

FIGS. 5A-5M are diagrams illustrating various intermediate structures in fabricating a thin body FET nanopore sensor in accordance with exemplary embodiments of the present invention;

FIG. 6 is a diagram of a thin body FET nanopore sensor in accordance with exemplary embodiments of the present invention shown in perspective view;

FIG. 7 is a diagram of a thin body FET nanopore sensor in accordance with exemplary embodiments of the present invention shown in perspective view with the annular STI oxide layer not shown; and

FIG. 8 is a diagram illustrating a cross-sectional structure of a thin body FET nanopore sensor including source, drain, and back gate contacts in accordance with exemplary embodiments of the present invention.

### DETAILED DESCRIPTION

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

Exemplary embodiments of the present invention provide a field effect transistor (FET) sensing device for sensing biomolecules and methods for fabricating and using the same. FET sensing devices make use of the fact that biomolecules tend to exhibit charge characteristics such as ionic charge or non-uniform distribution of charge that give rise to dipole moments. Thus, the proximity of biomolecules to the FET can influence the channel potential of the FET and thereby shift the threshold voltage Vₜ or FET drain current. For example, large drain current change in the presence of charged species may be observed as a sub-threshold slope of the FET which is the change in gate voltage of the FET required to induce a drain current change of one order of magnitude. Each distinct biomolecule may influence the channel potential of the FET in a different way and therefore, a signature may be recognized for each biomolecule, for example, based on sub-threshold sensing. For example, the charge and its spatial distribution and spatial location of the biomolecule modifies the threshold voltage of the FET which can be sensed by monitoring the drain current in the sub-threshold region. Thus, the biomolecule's charge and transit time may be used to fingerprint the particular biomolecule and thereby simultaneously detect the presence of multiple biomolecules. In this way, exemplary embodiments of the present invention may use a single sensor to test for a wide variety of different biomolecules without the need to provide biomolecule-specific surface functionalization.

FET sensors according to exemplary embodiments of the present invention may include a nanopore for allowing the biomolecules to gain proximity to the FET source, channel and drain. The nanopore may have a diameter slightly larger than the biomolecules being tested. This small volume of the nanopore may reduce the likelihood of multiple molecules being sensed at the same time. Thus the quantities of charge on a single molecule may be sensed. Where a single sensing device includes an array of FETs, nanopores thereof may be of multiple differing sizes to accommodate a range of different biomolecules. Such an array may also be used to simultaneously sense different types of biomolecules using a single sensor device.

As will be described in detail below, the source and drain of the FET may be relatively close together, for example, between approximately 20 nanometers to approximately 100 nanometers. This configuration may provide for an optimum travel distance to sense the biomolecules as they move between source and drain. This FET sensor is referred to as “thin body FET sensor” as the annular thickness of the silicon layer between the STI and nanopore is relatively thin, for example 10 to 20 nm. In particular, a thick silicon body may adversely impact the electrostatic control of the FET. To accommodate a thick silicon body, the FET may require relatively shallow junctions and high body doping to achieve acceptable electrostatic control, a measure of which is the sub-threshold slope. Accordingly, by using a relatively thin silicon body, exemplary embodiments of the present invention may not require shallow junctions or high body doping to achieve acceptable electrostatic control.

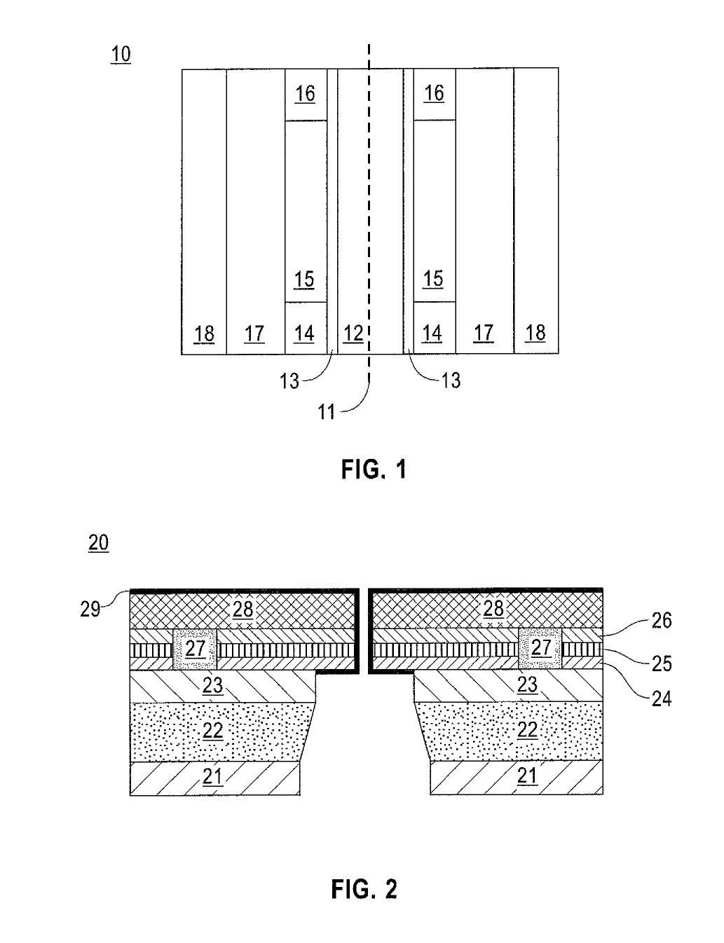

FIG. 1 is a cross-sectional schematic diagram illustrating a thin body FET nanopore sensor in accordance with exemplary embodiments of the present invention. The FET sensor 10 includes a silicon on insulator (SOI) structure (14, 15, and 16). The SOI structure includes a source 14, a drain 16, and a thin silicon body 15 interposed therebetween. The SOI structure has an annular ring shape and FIG. 1 depicts a cross-section of this annular ring shape. This SOI structure annular thickness is small and is typically between5 and 20 nm, and may be, for example, 10 nm. The distance between source 14 and drain 16 is relatively thin (a vertical thickness as shown in FIG. 1). This distance may be on the order of 5 nm to 100 nm and may be, for example, 25 nm. FIG. 1 and the other figures herein may not be drawn to scale.

A gate dielectric 13 is disposed on the SOI structure (14, 15, and 16). The gate dielectric is positioned between the SOI structure (14, 15, and 16) and a liquid gate 12. The gate dielectric 13 may be on the order of between 1 and 3 nm in cross-sectional thickness. The liquid gate 12 may be the nanopore opening filled with solution and the biomolecule to be tested may travel therethrough. The nanopore may be on the order of 5 to 30 nm in diameter, for example, 20 nm in diameter. The biomolecule may take a path through the liquid gate 12 and a liquid medium that the biomolecule is suspended within may flow though the liquid gate 12. The liquid gate acts as a physical gate by virtue of the biomolecules within the liquid medium moving in response to the electric field generated by the source 14 and drain 16 provided they have a size smaller than the nanopore diameter. A charge neutral region 11 may be present within the liquid gate 12 as the charged biomolecules are drawn towards the SOI structure (14, 15, and 16). The charge-neutral region acts as a FET gate and its electrical potential can be controlled externally by using an electrode.

An oxide layer 17 is disposed on the SOI structure (14, 15, and 16), for example, as shown in FIG. 1. The oxide layer 17 may be a shallow trench isolation (STI) for preventing current leakage between the SOI structure (14, 15, and 16) and a back gate.

An outer layer 18 may be disposed on the oxide layer 17. The outer layer 18 may include a conductor such as a doped semiconductor. For example, the outer layer 18 may include doped silicon or a metal. The outer layer 18 may serve as the back gate for the FET, which may be used for sensing as an alternative the liquid gate 12. Alternatively, the back-gate can be reverse biased to increase sensitivity of the FET sensor using the liquid gate as sensing gate.

FIG. 2 is a diagram illustrating a cross-sectional structure of a thin body FET nanopore sensor in accordance with exemplary embodiments of the present invention. It is to be understood that a sensing device may incorporate an array of FETs and what is illustrated in FIG. 2, for the purpose of providing a simple explanation, is a single FET. It is to be understood that contacting schemes using conventional or 3D interconnect can be employed

The FET structure 20 includes a base layer 21. The base layer 21 may include silicon nitride Si₃N₄ as an insulator and/or chemical barrier. The base structure 21, like the other structures depicted herein, is annular and a cross section is shown. A silicon layer Si 22 is disposed on the silicon nitride layer 21. A silicon dioxide SiO₂ layer 23 is disposed on the silicon layer 22. Together, the shape of the silicon nitride base layer 21, the silicon layer 22, and the silicon dioxide layer 23 create a cavity where the liquid medium of the biomolecule can flow to without interfering with the ability for additional biomolecules to flow.

The source 26, body 25, and drain 24 are disposed over the silicon dioxide layer 23. The STI 27 is disposed surrounding the source 26, body 25, and drain 24 (SOI), for example, as shown. A top layer 28, for example, also including silicon nitride, may be disposed over the STI 27 and SOI (24, 25, and 26). The nanopore may be formed as the space within the SOI (24, 25, and 26) and the silicon nitride top layer 28. The nanopore may thus open into the cavity created by the silicon nitride base layer 21, the silicon layer 22, and the silicon dioxide layer 23. A gate dielectric layer 29 may be disposed over a top surface of the silicon nitride top layer 28 and this gate dielectric layer 29 may also cover the outer surface of the nanopore, for example, as shown.

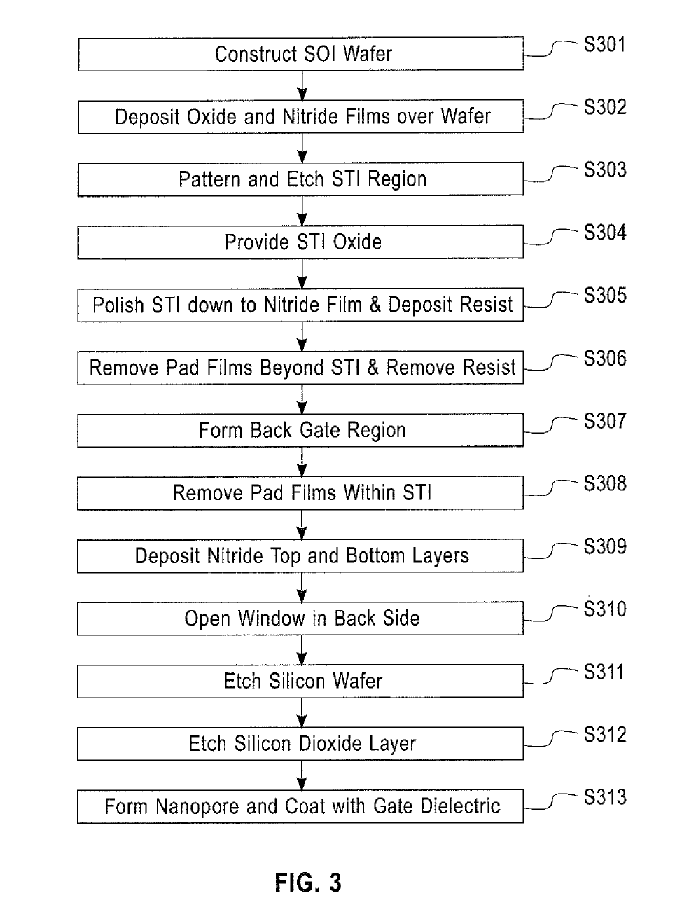

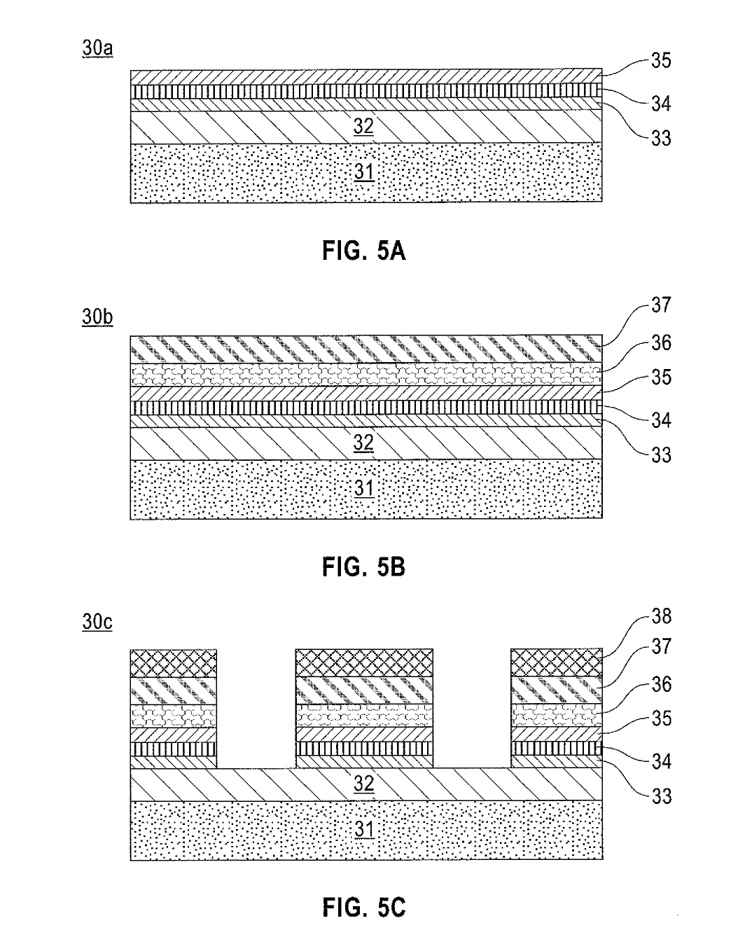

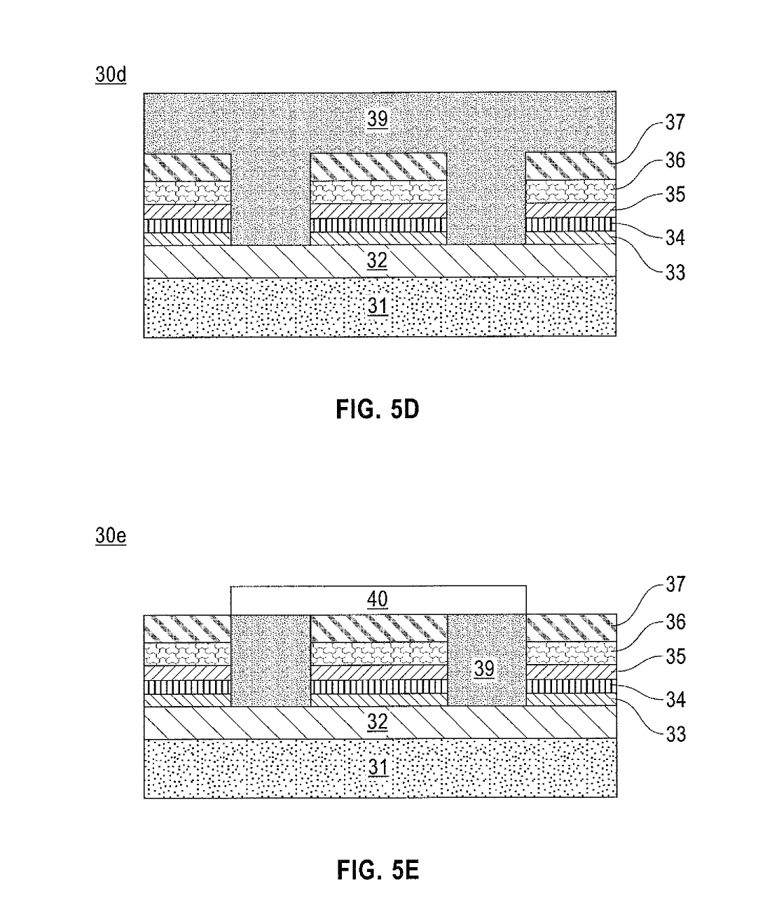

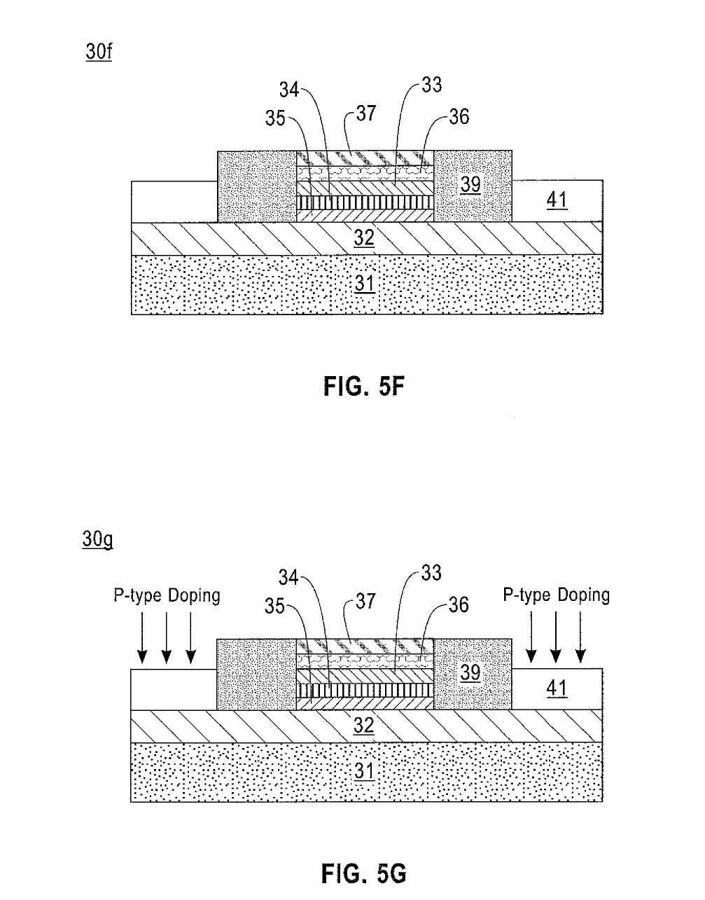

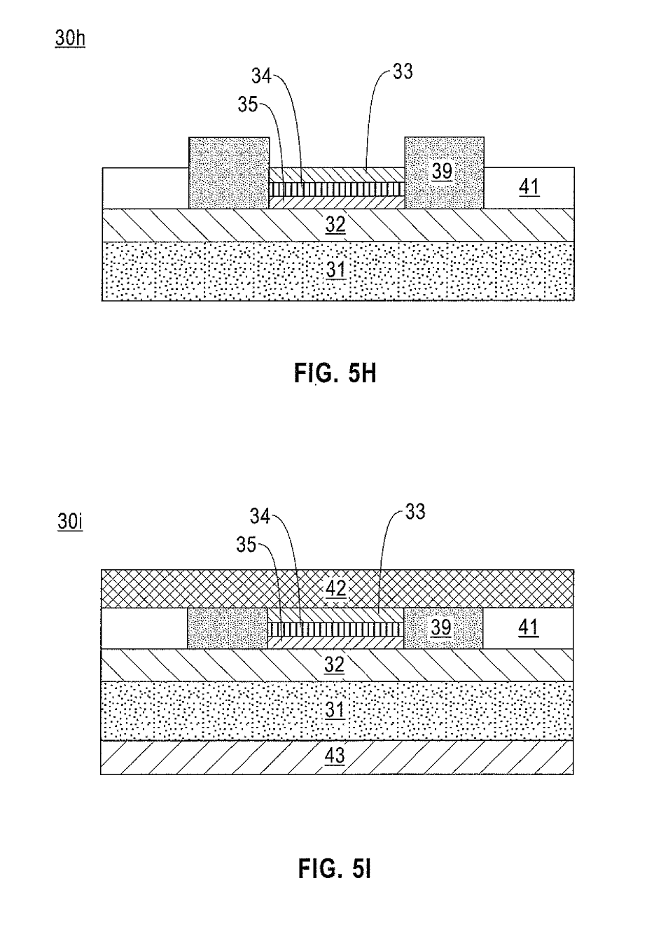

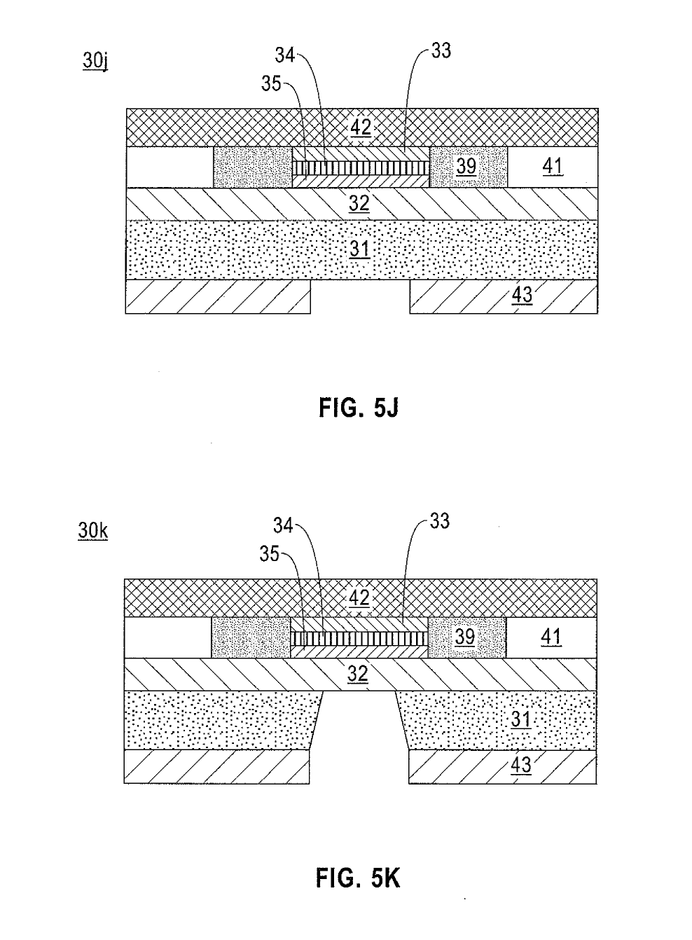

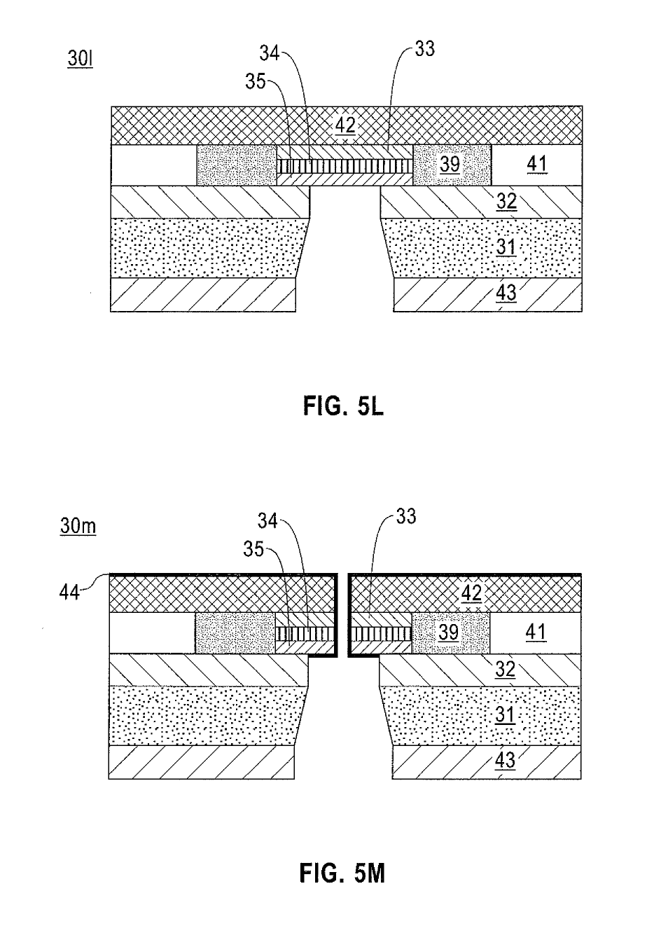

FIG. 3 is a flow chart illustrating a method for fabricating a thin body FET nanopore sensor in accordance with exemplary embodiments of the present invention. FIGS. 5A-5M are schematic diagrams showing select stages within the method illustrated in FIG. 3. A method for fabricating the nanopore sensor will now be described with reference to FIGS. 3 and 5A-5M.

First, a starting SOI wafer 30a (FIG. 5A) comprising a silicon dioxide layer 32 over a silicon wafer 31 and a doped silicon source layer 35 is used. A channel layer 34, and a source layer 33 are grown epitaxially over the drain layer 35 (Step S301). The epitaxial layers may be in-situ doped during deposition to prevent aggressive dopant activation.

Next, a thin pad oxide film 36, for example, including silicon dioxide, may be deposited over a top side of the SOI wafer and a pad nitride film 37, for example, including silicon nitride, may be disposed over the thin pad oxide film 36 (Step S302) to form intermediate structure 30b (FIG. 5B).

Next, STI regions may be patterned by depositing a resist 38, patterning the resist 38, and performing an RIE etch down to the silicon dioxide layer 32, which may be referred to herein as the “box” (Step S303). This may result in intermediate structure 30c (FIG. 5C).

Next, the resist 38 may be stripped, an STI liner layer (not shown) may be grown, and an STI oxide 39 may be deposited and annealed (Step S304) to create the intermediate structure 30d (FIG. 5D). The STI liner may be provided to help the STI layer form properly and the liner may be incorporated into the STI structure thereafter.

Next, CMP may be performed to polish the STI oxide 39 down to the nitride pad film 37 and thereafter, a resist layer 40 may be deposited over the STI oxide 39 and the space therewithin (Step S305). This may result in intermediate structure 30e (FIG. 5E). The resist layer 40 covers the nanopore region and exposes the back gate region.

Next, the pad oxide film 36 and the pad nitride film 37 may be removed beyond the bounds of the resist 40 and then the resist may be removed (Step S306) to form intermediate structure 30f (FIG. 5F). In this step, REI etching may be used to remove the pad oxide film 36 and the pad nitride film 37. The resist may be removed subsequently.

Then low energy implantation may be used to form the back-gate region 41 and the back gate region 41 may then be activated by performing mild RTA annealing (Step S307). A photoresist may be applied to expose only the back-gate region to this implant. P-type dopants may be used for this implantation. This may result in intermediate structure 30g (FIG. G). Alternatively, in situ p-doped selective epi growth may also be used to grow the back gate region 41 after thinning the exposed region 41 sufficiently and performing a low energy P-type dopant implantation.

Then, the pad nitride 37 and pad oxide 36 layers may be removed from within the STI 39 (Step S308). This may result in intermediate structure 30h (FIG. H).

Then, a top nitride layer 42, for example, including silicon nitride may be disposed over the STI and SOI, and a bottom nitride layer 43 may be deposited under the silicon wafer 31 (Step S309). This may result in intermediate structure 30i (FIG. 5I).

Next, a window may be opened on the bottom nitride layer 43, for example, using photolithography and reactive ion etching (Step S310). This may result in intermediate structure 30j (FIG. 5J).

The bulk silicon wafer 31 may then be etched through, for example, using a KOH or TMAH solution at 80° C. to form a freestanding membrane (Step S311). This may result in intermediate structure 30k (FIG. 5K).

Next, the silicon dioxide layer 32 may be etched, for example, in a dilute HF solution to expose the area of the freestanding membrane (Step S312). This may result in intermediate structure 30L (FIG. 5I).

Thereafter, the nanopore may be formed through the freestanding membrane of the top nitride layer 42, source 35, channel 34, and drain 33, for example, using TEM, FIB, or simple lithography followed by reactive ion etching and thereafter the nanopore may be coated with a gate dielectric 44 (Step S313). The gate dielectric may include hafnium(IV) oxide HfO₂ and may be coated using an atomic layer deposition method. This may result in the final structure 30m (FIG. 5M).

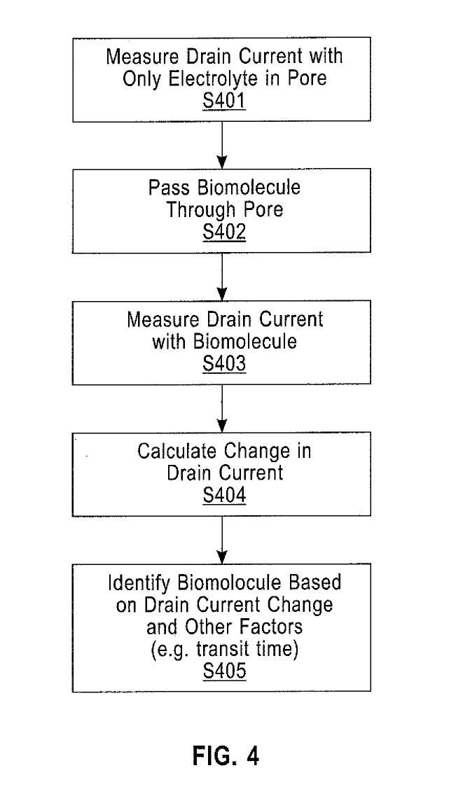

The thin body FET nanopore sensor, so formed, may be used to sense or screen biomolecules. FIG. 4 is a flow chart illustrating an approach for sensing biomolecules within a fluid sample in accordance with exemplary embodiments of the present invention. First, a drain current I_{d} may be measured from the drain of the FET nanopore sensor at a time when there is no biomolecule present in the nanopore (Step S401). For example, there might only be an electrolyte present within the nanopore. Next, the solution containing the biomolecule may be applied to the FET nanopore sensor while the drain current is continuously monitored so that the biomolecule may pass through the nanopore (Step S402). The drain current may thereby be measured while the biomolecule passes between the source and drain within the nanopore (Step S403). From there, a change in drain current may be calculated between the drain current without the biomolecule and the drain current with the biomolecule (Step S404). This difference may be used, among other factors, to identify the biomolecule based on the drain current change (Step S405). These other factors may include, for example, a time required for the biomolecule to pass through the nanopore or the duration for which a change in drain current is observed.

As sensing is being performed, biomolecules within the medium may become arranged in response to an electric field created between a source and drain of the thin body nanopore sensor and may thereby form a fluid gate. The fluid gate may be set at a desired voltage V_{g} using an electrode. This may typically be a relatively low positive voltage ensuring the device is in the subthreshold regime. As described above, in some exemplary embodiments of the present invention, an outer layer may serve as a back gate for sensing the drain current. Here, the back gate may be set to a slightly positive bias ensuring the FET sensor is in the subthreshold regime and in this case the back-gate may be doped n-type. However, where the outer layer is not used as a back gate, it may have a slightly negative bias with p-type doping to increase the sensor sensitivity when sensing with liquid gate.

The transit time of a bio-molecule through the nanopore may depend upon the fluid flow rate as well as the mobility of the molecule. The mobility determines the drift velocity of the bio-molecule through the pore as there is an electric field in the liquid between the ends of the nanopore. The electric field results from the different biases on source and drain. As different bio-molecules have different mobilities (different mass and shape), determining the transit time may also provide information about the type of bio-molecule being sensed in addition to using the net charge, which may be determined from an amount of change-in-drain current during the transit time in the nanopore.

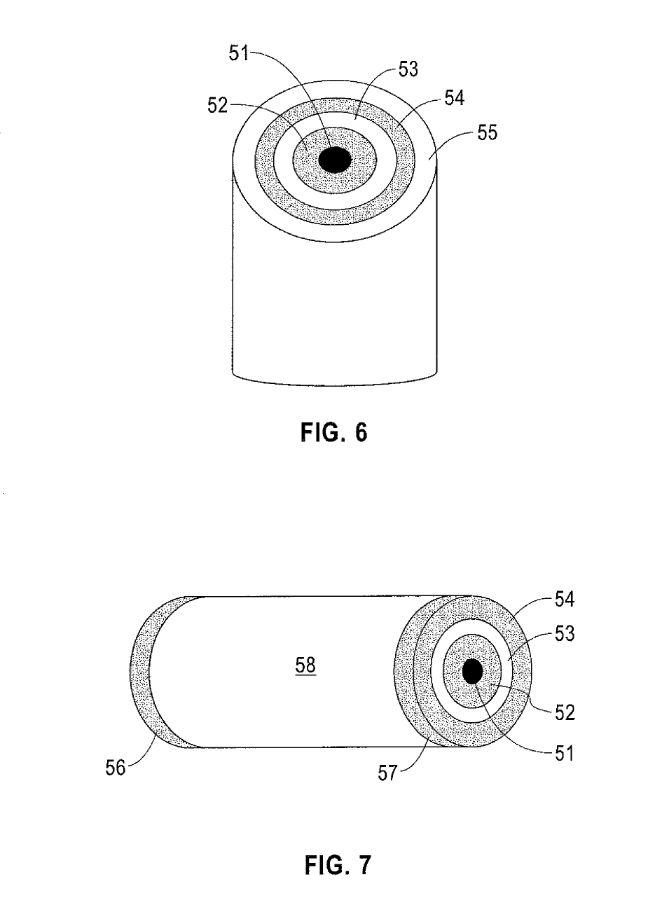

FIG. 6 is a diagram of a thin body FET nanopore sensor in accordance with exemplary embodiments of the present invention shown in perspective view. As can be seen from this view, the liquid gate nanopore 52 is at the center of the structure. The liquid gate nanopore 52 may be an opening filled with the solution, however, there may also be a neutral body within this liquid 51 therein serving as the FET gate and contacted by an electrode for maintaining desired voltage. Around the liquid gate nanopore 52 is the gate dielectric layer 53 (gate oxide), which is shaped as an annular ring. Around the gate dielectric layer 53 is the thin body SOI 54, which is also shaped as an annular ring, and includes a source, drain and a thin silicon body disposed therebetween. Around the SOI 54 is the oxide layer 55, also called the “box.” The back gate is not shown but would be formed around the oxide layer 55.

FIG. 7 is a diagram of a thin body FET nanopore sensor in accordance with exemplary embodiments of the present invention shown in perspective view with the oxide layer 55 not shown. With the oxide layer 55 not shown, the SOI 54 can be seen as including a source 57 at one side, a drain 56 at an opposite side, and the silicon channel 58 interposed therebetween and acting as a channel region. The term “thin” as used in this context, refers to the annular thickness.

The source and drain may be doped, for example, with an n-type dopant on the order of 1 to 10×10¹⁹ parts per cubic cm. The channel may be undoped or may be doped with a p-type dopant up to approximately 1 to 3×10¹⁸ parts per cubic cm.

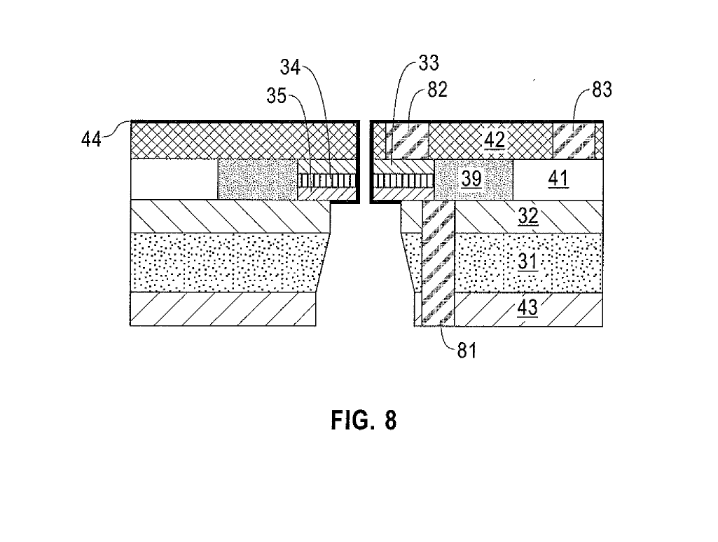

The source, drain and back gate of the sensor device may include contacts. FIG. 8 is a diagram illustrating a cross-sectional structure of a thin body FET nanopore sensor including source, drain, and back gate contacts in accordance with exemplary embodiments of the present invention. While the source contact 82 and the back gate contact 83 may be formed from the top side down, the drain contact 81 may be formed from the bottom side up. Contact windows may be formed by performing photolithography and/or reactive ion etching. Thereafter, the contact metal may be filled into the contact windows. A contact metal liner may also be deposited into the contact windows prior to performing the filling with the contact metal. In creating the drain contact 81 in this way, this process may be performed after depositing the nitride top 42 and bottom 43 layers S309, after which point, the opening created in the nitride bottom layer 43 may be filled in with nitride prior to continuing as described above. To facilitate the construction of the drain contact, the bulk Silicon region 31 can be thinned prior to backside nitride 43 deposition.

Exemplary embodiments described herein are illustrative, and many variations can be introduced without departing from the spirit of the disclosure or from the scope of the appended claims. For example, elements and/or features of different exemplary embodiments may be combined with each other and/or substituted for each other within the scope of this disclosure and appended claims.

What is claimed is:

1. A thin body field effect transistor (FET) nanopore sensor, comprising:
a silicon on insulator (SOI) structure having an annular shape and comprising a source, a drain and a thin body channel interposed therebetween;
a nanopore formed in a central opening of the SOI structure;
a gate dielectric disposed on the SOI structure insulating the SOI structure from a liquid gate within the nanopore;
a back gate formed around the SOI structure; and
a shallow trench isolation (STI) layer formed between the SOI structure and the back gate.

2. The FET nanopore sensor of claim 1, additionally comprising a cavity formed below the liquid gate for receiving biomolecules and solution that pass through the micropore.

3. The FET nanopore sensor of claim 1, wherein the cavity comprises:
an oxide layer of the SOI structure formed below the gate and STI layer;
a semiconductor layer of the SOI structure formed below the oxide layer; and
a nitride layer formed below the SOI structure,
wherein the oxide layer, the semiconductor layer, and the nitride layer each have an annular shape with a relatively large central opening and the openings of the oxide layer, the semiconductor layer, and the nitride layer together form the cavity.

4. The FET nanopore sensor of claim 3, wherein the oxide layer includes silicon dioxide, the semiconductor layer includes silicon, and the nitride layer includes silicon nitride.

5. The FET nanopore sensor of claim 1, wherein the thin body channel has a length of between approximately 15 nm to approximately 100 nm from the source to the drain.

6. The FET nanopore sensor of claim 5, wherein the thin body channel has a length of approximately 25 nm from the source to the drain.

7. The FET nanopore sensor of claim 1, wherein the gate dielectric has a thickness of between approximately 1 nm to approximately 3 nm.

8. The FET nanopore sensor of claim 1, wherein the nanopore has a diameter of between approximately 3 nm to approximately 50 nm.

9. The FET nanopore sensor of claim 1, wherein the nanopore has a diameter sufficient to allow only a single biomolecule to pass therethrough at a time

10. The FET nanopore sensor of claim 1, wherein the FET nanopore sensor is part of a sensing device including an array of similar FET nanopore sensor.

11. The FET nanopore sensor of claim 10, wherein the similar FET nanopore sensors have a set of different nanopore diameters for sensing various different biomolecules.

12. The FET nanopore sensor of claim 1, wherein the source and drain regions are formed by doping corresponding regions of the SOI structure with an n-type dopant.

13. The FET nanopore sensor of claim 12, wherein the source and drain regions are doped to a concentration of approximately 1 to 10×10¹⁹ parts per cubic cm.

14. The FET nanopore sensor of claim 1, wherein the channel region is formed by doping corresponding regions of the SOI structure with a p-type dopant to a concentration of no more than approximately 1 to 3×10¹⁸ parts per cubic cm.

15. The FET nanopore sensor of claim 1, wherein the back gate includes a conductor or a semiconductor.

16. The FET nanopore sensor of claim 15, wherein the back gate includes doped silicon or a metal.

17. The FET nanopore sensor of claim 1, wherein the STI includes silicon dioxide.

18. The FET nanopore sensor of claim 1, additionally comprising a top layer including silicon nitride formed over the STI layer and SOI structure and formed under the gate dielectric.

19. The FET nanopore sensor of claim 1, wherein the gate dielectric includes hafnium(IV) oxide or a combination of silicon-oxide and hafnium oxide.

20. The FET nanopore sensor of claim 1, wherein the STI has an annular thickness of between approximately 10 nm to 100 nm, as measured between the SOI structure and the back gate.

21. A method for fabricating a thin body field effect transistor (FET) nanopore sensor, comprising:
providing a bulk silicon wafer including with an oxide insulator thereon, and a silicon layer over the oxide insulator, the combination of the bulk silicon wafer, the oxide insulator and the silicon layer over the oxide insulator being referred to as a silicon on insulator (SOI) structure;
forming doped silicon regions the oxide insulator to form a source, drain and a thin body channel region therebetween;
depositing an oxide film over the SOI structure and a nitride film over the oxide film;
patterning and etching a shallow trench isolation (STI) region within the silicon layer over the oxide insulator;
depositing an oxide within the etched STI region;
planarizing the oxide within the etched STI region down to the nitride film;
removing the oxide and nitride films beyond the STI regions down to the silicon layer over the oxide insulator;
forming doped silicon region beyond the STI to form a hack gate;
removing the pad oxide and pad nitride layers inside the annular STI region;
forming a top nitride layer over the SOI and STI regions;
forming a bottom nitride layer under the bulk silicon wafer;
opening a window within the bottom nitride layer;
etching the bulk silicon wafer through the opening of the bottom nitride layer to form an opening in the bulk silicon wafer;
etching the oxide insulator of the SOI through the opening in the bulk silicon wafer;
forming a nanopore through the top nitride layer and the SOI; and
coating walls of the nanopore and the top nitride layer with a gate dielectric.

22. A method for detecting a biomolecule using a thin body field effect transistor (FET) nanopore sensor, comprising:
measuring a drain current without a biomolecule in a nanopore of the thin body FET nanopore sensor;
passing a biomolecule through the nanopore;
measuring the drain current of the thin body FET nanopore sensor as the bio-molecule passes from a source electrode of the sensor, past a thin body channel region of the sensor, to a drain region of the sensor; and
identifying the biomolecule based on a change in drain current between when the drain current was measured without the biomolecule passing through the nanopore and when the drain current was measured with the biomolecule passing through the nanopore,
wherein a sensitivity of the sensor is increased by a presence of a shallow trench isolation (STI) region within a plane of the source, channel and drain that enables formation of a thin annular silicon body for the FET sensor.

23. The method of claim 22, wherein the sensitivity of the sensor is further increased by a back gate within the plane of the source, channel and drain.
